(19) United States
(12) Patent Application Publication
(10) Pub. No.: US 2018/0068855 A1
(43) Pub. Date: Mar. 8, 2018

(54) Method of Manufacturing Thin Film Transistor

(71) Applicant: Shenzhen China Star Optoelectronics Technology Co., Ltd., Shenzhen, Guangdong (CN)

(72) Inventor: Liangyi CAI, Shenzhen, Guangdong (CN)

(73) Assignee: Shenzhen China Star Optoelectronics Technology Co. , Ltd., Shenzhen, Guangdong (CN)

(21) Appl. No.: 15/119,718

(22) PCT Filed: Jul. 12, 2016
(86) PCT No.: PCT/CN2016/089760

§ 371 Date: Aug. 17, 2016

(30) Foreign Application Priority Data
Jan. 28, 2016 (CN) 201610061764.0

(51) Int. Cl. H01L 21/28; H01L 29/51; H01L 29/786; H01L 29/66; H01L 29/49

(52) U.S. Cl. CPC H01L 21/28008; H01L 29/51; H01L 29/4908; H01L 29/66969; H01L 29/7869

(57) ABSTRACT

The present disclosure provides a method of manufacturing a thin film transistor, the method comprises: to provide a substrate, to provide a gate electrode on the substrate, to provide an insulating layer on the gate electrode, to provide a semiconductor layer on the gate insulating layer, to respectively provide a source electrode and a drain electrode, to provide a passivation layer on the source electrode and the drain electrode, to provide a pixel electrode on the passivation layer, wherein said gate insulating layer is formed of a porous SiO₂.

### BACKGROUND OF THE DISCLOSURE

### 1. Field of the Disclosure

The present disclosure relates to a thin film transistor field, and in particular to a method of manufacturing a thin film transistor.

### 2. The Related Arts

A color thin film transistor liquid crystal display, TFT-LCD, is mainly used in computers, video terminals, communications and instrumentation industries. The main application fields comprise laptops, desktop computer monitors, workstations, industrial monitors, global positioning system (GPS), personal data processing, consoles, video phones, portable VCD, DVD and other portable devices. Through constant development and innovation, TFT-LCD is rapidly growth of the mainstream display.

The working principle of the TFT-LCD is to control the switch of each pixel through the voltage variation, precisely controlling the color and the brightness of each pixel, thereby obtaining the required screen.

Now the TFT-LCD of the mainstream market requires larger voltage (the driver voltage is generally greater than 10V) to normally operate, and needs adequate current switching ratio. The larger working voltage results more consumption and larger parasitic capacitance, It is not conducive to portable electronic product design.

Chinese patent application of publication No. CN103762178A discloses a method for producing a low-temperature polysilicon thin film transistor, the method comprises forming the composite gate insulating layer through multiple PECVD process, wherein said gate insulating layer comprises SiO₂. The process of the method is complicated, and the manufacturing cost is increased.

### SUMMARY OF THE DISCLOSURE

The object of the present disclosure is to overcome the deficiencies of the prior art, providing a method of manufacturing TFT that can reduce the working voltage of TFT-LCD and decrease the parasitic capacitance. The method can improve the working voltage of TFT, thereby improving the quality of TFT products, reducing the power consumption.

According to the embodiments of the present disclosure, which provides a method of manufacturing a thin film transistor, the method comprises the following steps: to provide a substrate, to provide a gate electrode on the substrate, to provide an insulating layer on the gate electrode, to provide a semiconductor layer on the gate insulating layer, to respectively provide a source electrode and a drain electrode, to provide a passivation layer on the source electrode and the drain electrode, to provide a pixel electrode on the passivation layer, wherein said gate insulating layer is formed of a porous SiO₂.

According to the embodiments of the present disclosure, the steps of forming the gate insulating layer comprises: SiH₄ and O₂ as reaction gases are deposited the porous SiO₂ as the gate insulating layer on the gate electrode.

According to the embodiments of the present disclosure, adopting a plasma enhanced chemical vapor deposition method to deposit the porous SiO₂.

According to the embodiments of the present disclosure, the thickness of said gate insulating layer is 5000 Å.

According to the embodiments of the present disclosure, the steps of forming semiconductor layer comprise: to deposit a photoresist layer on the gate insulating layer in order to cover most of the surface of the gate insulating layer; to use H₃PO₄ to process exposed area of the gate insulating layer in order to make —PO₃H₂ entered the porous SiO₂ of the gate insulating layer; to deposit a semiconductor oxide on the photoresist and the exposed area of the gate insulating layer, and then to strip the photoresist layer and the semiconductor oxide deposited on the photoresist layer, thereby forming the semiconductor layer.

According to the embodiments of the present disclosure, adopting a physical vapor deposition method to deposit the semiconductor oxide on the exposed gate insulating layer and the photoresist layer.

According to the embodiments of the present disclosure, using H₃PO₄ to process the gate insulating layer comprises showering and/or soaking the gate insulating layer by using 60 wt %˜80 wt % H₃PO₄.

According to the embodiments of the present disclosure, the photoresist layer is a positive photoresist layer.

According to the embodiments of the present disclosure, the thickness of the photoresist is 1 um-2 um.

According to the embodiments of the present disclosure, the semiconductor layer comprises indium gallium zinc oxide.

Through the above descriptions of the present disclosure combining the exemplary embodiments, according to the method of manufacturing a thin film transistor of the present disclosure can improve the TFT working voltage, thereby improving the quality of TFT products, reducing the power consumption.

### BRIEF DESCRIPTION OF THE DRAWINGS

Through the following descriptions of the exemplary embodiments combining the drawings, each aspect of the present disclosure will become clearer.

FIG. 1 is to schematically show the steps of manufacturing gate electrode according to the method of manufacturing a thin film transistor of the exemplary embodiment of the present disclosure;

FIG. 2 is to schematically show the steps of manufacturing gate insulating layer according to the method of manufacturing a thin film transistor of the exemplary embodiment of the present disclosure;

FIG. 3A-FIG. 3C is sequentially and schematically show the steps of manufacturing semiconductor layer according to the method of manufacturing a thin film transistor of the exemplary embodiment of the present disclosure, wherein FIG. 3A is to schematically show the steps of providing the photoresist layer according to the method of manufacturing a thin film transistor of the exemplary embodiment of the present disclosure, FIG. 3B is to schematically show the steps of providing the semiconductor oxide on the exposed gate insulating layer and the photoresist layer according to the method of manufacturing a thin film transistor of the exemplary embodiment of the present disclosure, FIG. 3C is to schematically show the steps of forming the island-shaped semiconductor layer on the gate insulating layer according to the method of manufacturing a thin film transistor of the exemplary embodiment of the present disclosure;

FIG. 4 is to schematically show the steps of respectively forming a source electrode, a drain electrode a passivation layer and a pixel electrode layer on the semiconductor layer according to the method of manufacturing a thin film transistor of the exemplary embodiment of the present disclosure.

### DETAILED DESCRIPTION OF THE PREFERRED EMBODIMENTS

The working principle of the TFT-LCD is to control the switch of each pixel through the voltage variation, precisely controlling the color and the brightness of each pixel, thereby obtaining the required screen. However, now the TFT-LCD of the mainstream market requires larger voltage (the driver voltage is generally greater than 10V) to normally operate, and needs adequate current switching ratio. The larger working voltage results more consumption and larger parasitic capacitance, It is not conducive to portable electronic product design.

The following will provide a method of manufacturing a thin film transistor referring to the exemplary embodiments of the present disclosure described as the drawings, the method uses SiH₄ and O₂ as reaction gases, through the method of PECVD deposit the porous SiO₂ as the TFT gate insulating layer, thereby effectively reducing the parasitic capacitance and decreasing the power consumption.

The following will combine the drawings to describe the exemplary embodiments of the present disclosure, however, the scope of protection of the present disclosure is not limited by the drawings and the exemplary embodiments described as following. The following description of the exemplary embodiments is to let those skilled in the art able to more fully understand the specific embodiment of the present disclosure, and to more fully convey the scope of the invention to those skilled in the art. In the drawings, the thickness of layers and regions can be exaggerated for clarity. Moreover, the same drawing numerals always refer to the same elements.

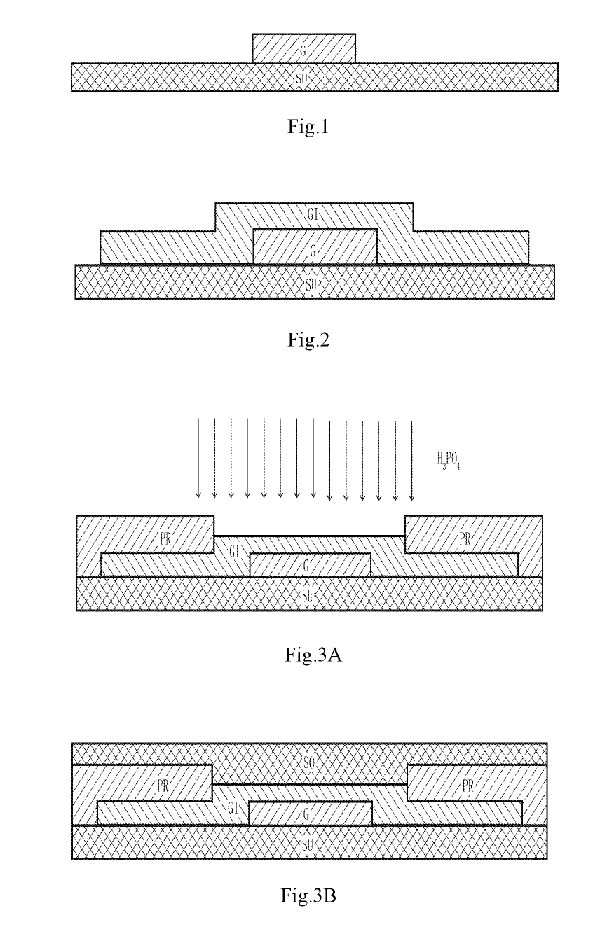

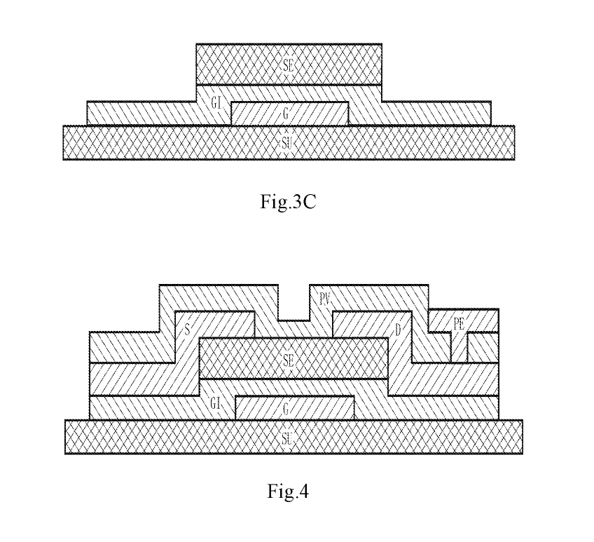

FIG. 1 is to schematically show the steps of manufacturing gate electrode according to the method of manufacturing a thin film transistor of the exemplary embodiment of the present disclosure. FIG. 2 is to schematically show the steps of manufacturing gate insulating layer according to the method of manufacturing a thin film transistor of the exemplary embodiment of the present disclosure. FIG. 3A-FIG. 3C is sequentially and schematically show the steps of manufacturing semiconductor layer according to the method of manufacturing a thin film transistor of the exemplary embodiment of the present disclosure, wherein FIG. 3A is to schematically show the steps of providing the photoresist layer according to the method of manufacturing a thin film transistor of the exemplary embodiment of the present disclosure, FIG. 3B is to schematically show the steps of providing the semiconductor oxide on the exposed gate insulating layer and the photoresist layer according to the method of manufacturing a thin film transistor of the exemplary embodiment of the present disclosure, FIG. 3C is to schematically show the steps of forming the island-shaped semiconductor layer on the gate insulating layer according to the method of manufacturing a thin film transistor of the exemplary embodiment of the present disclosure. FIG. 4 is to schematically show the steps of respectively forming a source electrode, a drain electrode a passivation layer and a pixel electrode layer on the semiconductor layer according to the method of manufacturing a thin film transistor of the exemplary embodiment of the present disclosure.

The following will combine FIG. 1 to FIG. 4 to fully described the method of manufacturing a thin film transistor of the exemplary embodiments of the present disclosure.

Refer to FIG. 1 to FIG. 4, the method of manufacturing a thin film transistor according to the exemplary embodiments of the present disclosure comprises the following steps:

First, as shown in FIG. 1, to provide a substrate SU, and to provide a gate electrode G on the substrate.

According to the exemplary embodiments of the present disclosure, the substrate SU could be the glass substrate that is commonly used in the prior art, but the present disclosure is not limited thereto. Moreover, between the substrate SU and the gate electrode G could be provided a buffer layer in order to avoid the metal particles entering the substrate SU during the etching.

And then, as shown in FIG. 2, on the exposed portion of the substrate SU and the gate electrode G is formed a gate insulating layer.

According to the exemplary embodiments of the present disclosure, the gate insulating layer GI is formed by porous SiO₂. Adopting a plasma enhanced chemical vapor deposition method, PECVD, to deposit the porous SiO₂ on the exposed portion of the substrate SU and the gate electrode G in order to form a gate insulating layer G1 with predicted thickness. Preferably, in the depositing process, SiH₄ and O₂ can be used as reaction gases in the room temperature (for example, 5° C.-35° C.). Preferably, the thickness of said gate insulating layer is 5000 Å, but the present disclosure is not limited thereto.

After forming the gate insulating layer GI, providing a semiconductor layer SE on the gate insulating layer GI, as shown in FIG. 3A to FIG. 3C.

According to the exemplary embodiments of the present disclosure, refer to the FIG. 3A to FIG. 3C, the steps of providing the semiconductor layer SE preferably comprise but not limited by the following aspects:

(1) To provide a photoresist layer PR on the gate insulating layer GI, as shown in FIG. 3A. Specifically, as shown in FIG. 3A, providing a photoresist layer PR with predicted thickness on the gate insulating layer GI, for example, 1 um-2 um, in order to cover the most surface of the gate insulating layer GI, and make the region corresponded with the gate insulating layer GI and the gate electrode G exposed, thereby protecting the metal lines. In other words, the photoresist layer PR is provided to make the portion of the gate insulating layer GI corresponded with the gate electrode G exposed, and covering the other regions of the gate insulating layer GI. The above object can be achieved by deposition and mask, but the present disclosure is not limited thereto. Moreover, preferably, after forming the photoresist layer PR, using H₃PO₄ (such as showering, soaking, etc.) with high concentration (such as 60 wt %˜80 wt %) to process the predetermined time period of the exposed region of the gate insulating layer GI, thereby making —PO₃H₂ entered the porous SiO₂ of the gate insulating layer.

(2) Depositing a semiconductor oxide SO on the exposed portion of the photoresist PR and the gate insulating layer GI, as shown in FIG. 3B. according to the exemplary embodiments of the present disclosure, adopting a physical vapor deposition method, PVD, to deposit the semiconductor oxide SO on the exposed gate insulating layer GI and the photoresist layer PR. Moreover, the semiconductor oxide SO according to the exemplary embodiments of the present disclosure cloud be indium gallium zinc oxide, IGZO.

(3) Using the stripping photoresist layer PR (for example, a positive photoresist layer) such as a stripping liquid and the semiconductor oxide SO (for example, IGZO) deposited on the photoresist layer PR, thereby forming a semiconductor layer SE, as shown in FIG. 3C. According to an exemplary embodiment of the present disclosure, because the region corresponded with the gate insulating layer GI and the gate electrode G is not formed a photoresist layer PR, namely, the region corresponded with the gate insulating layer GI and the gate electrode G is directly contacted with the semiconductor layer SE, therefore, after stripping the photoresist layer PR, the semiconductor layer SE on the region corresponded with the gate insulating layer GI and the gate electrode G is not stripped and kept on the gate insulating layer GI. According to an exemplary embodiment of the present disclosure, after the photoresist layer PR and the semiconductor oxide SO deposited on the photoresist layer stripped, forming a island-shaped IGZO semiconductor layer SE.

After forming the semiconductor layer SE, respectively providing a source electrode S and a drain electrode D, a passivation PV and a pixel electrode layer PE on the semiconductor SE according to the prior art. For example, as shown in FIG. 4, according to the exemplary embodiments of the present disclosure, the source electrode S and drain electrode D can be formed on the semiconductor layer SE by using the method of deposition or mask, so that those are located on the same layer, and then forming a passivation PV on the source electrode S and the drain electrode D, and forming a pixel electrode PE on the formed passivation, thereby manufacturing a thin film transistor.

In summary, the method of manufacturing a thin film transistor according to the exemplary embodiments of the present disclosure is described in detail through combining the drawings. Through the above method, adopting the porous SiO₂ as a gate insulating layer, making the TFT channel and the TFT channel electronic coupled with each other to form a large electric double layer, EDL, under the electric field driven. Moreover, after the gate insulating layer formed, processing the porous SiO₂ through H₃PO₄, enhancing the proton conductive feature of the processed porous SiO₂. This is because of the interaction of —PO₃H₂ connected with the particle surface of SiO₂ and forming Grotthuss chain, and the H+ can freely jump in the transport network consisted by Grotthuss chain, enhancing the proton transfer capability of the thin film. The EDL capacitor after phosphate treatment is increased so that the coupling between the gate electrode and the channel is enhanced, thereby the gate voltage can be induced more channel electronic, reducing the parasitic capacitance and decreasing the working voltage.

What is claimed is:

1. A method of manufacturing a thin film transistor, wherein said method comprises following steps:
to provide a substrate;
to provide a gate electrode on the substrate;
to provide an insulating layer on the gate electrode;
to provide a semiconductor layer on the gate insulating layer;
to respectively provide a source electrode and a drain electrode;
to provide a passivation layer on the source electrode and the drain electrode;
to provide a pixel electrode on the passivation layer;
wherein said gate insulating layer is formed of a porous SiO₂.

2. The method as claimed in claim 1, wherein the steps of forming gate insulating layer comprise:
SiH₄ and O₂ as reaction gases are deposited the porous SiO₂ as the gate insulating layer on the gate electrode.

3. The method as claimed in claim 2, wherein adopting a plasma enhanced chemical vapor deposition method to deposit the porous SiO₂.

4. The method as claimed in claim 2, wherein the thickness of said gate insulating layer is 5000 Å.

5. The method as claimed in claim 1, wherein the steps of forming semiconductor layer comprise:
to deposit a photoresist layer on the gate insulating layer in order to cover most of the surface of the gate insulating layer;
to use H₃PO₄ to process exposed area of the gate insulating layer in order to make —PO₃H₂ entered the porous SiO₂ of the gate insulating layer;
to deposit a semiconductor oxide on the photoresist and the exposed area of the gate insulating layer, and then to strip the photoresist layer and the semiconductor oxide deposited on the photoresist layer, thereby forming the semiconductor layer.

6. The method as claimed in claim 5, wherein adopting a physical vapor deposition method to deposit the semiconductor oxide on the exposed gate insulating layer and the photoresist layer.

7. The method as claimed in claim 5, wherein using H₃PO₄ to process the gate insulating layer comprises showering and/or soaking the gate insulating layer by using 60 wt %˜80 wt % H₃PO₄.

8. The method as claimed in claim 5, wherein the photoresist layer is a positive photoresist layer.

9. The method as claimed in claim 5, wherein the thickness of the photoresist is 1 um-2 um.

10. The method as claimed in claim 1, wherein the semiconductor layer comprises indium gallium zinc oxide.
